(19) United States
(12) Patent Application Publication
(10) Pub. No.: US 2018/0035575 A1
(43) Pub. Date: Feb. 1, 2018

(54) SLURRY DISPENSING APPARATUS FOR EMI SHIELDING

(71) Applicant: PROTEC CO., LTD., Gyeonggi-do (KR)

(72) Inventor: SEUNG MIN HONG, INCHEON (KR)

(73) Assignee: PROTEC CO., LTD., Gyeonggi-do (KR)

(21) Appl. No.: 15/663,823

(22) Filed: Jul. 31, 2017

(30) Foreign Application Priority Data
Aug. 1, 2016 (KR) 10-2016-0098135

(51) Int. Cl. H05K 9/00; B05C 11/10; B05C 5/02

(52) U.S. Cl. CPC H05K 9/0083; B05C 5/02; B05C 11/1007

(57) ABSTRACT

Provided is a slurry dispensing apparatus for electromagnetic interference (EMI) shielding, and more particularly, a slurry dispensing apparatus for EMI shielding, wherein the slurry dispensing apparatus dispenses a slurry, in which a conductive metal powder and an adhesive are mixed, to an electronic component to form an electromagnetic wave shielding layer on the electronic component.

By using the slurry dispensing apparatus for EMI shielding, the slurry may be dispensed while preventing separation of the metal powder included in the slurry from the adhesive by precipitation, and maintaining a uniform mixture ratio in the slurry.

### CROSS-REFERENCE TO RELATED APPLICATION

This application claims the priority benefit of Korean Patent Application No. 10-2016-0098135, filed on Aug. 1, 2016, in the Korean Intellectual Property Office. The disclosure of which is incorporated herein in its entirety by reference.

### BACKGROUND

### 1. Field

One or more example embodiments relate to an apparatus for dispensing a slurry for electromagnetic interference (EMI) shielding, and more particularly, to an apparatus for dispensing a slurry, in which a conductive metal powder and an adhesive are mixed, to an electronic component in order to form an electromagnetic wave shielding layer on the electronic component.

### 2. Description of the Related Art

Electromagnetic interference (EMI) refers to a disturbance caused by an electromagnetic wave that is directly radiated or transmitted from an electric or electronic device and hinders an electromagnetic receiving function of another device. EMI causes various problems such as degradation of functions and reliability of a device and increase in heat emitted from the devices.

The EMI may be resolved through three methods, which are a reflection method in which an electromagnetic wave is returned to the device that generated the electromagnetic wave, a by-pass method in which EMI is passed on to another place by using a reflection method or a grounding method, and a shielding method in which a slurry that prevents electromagnetic radiation is dispensed to a product that is likely to generate EMI. Meanwhile, a slurry refers to a mixture of a conductive metal powder having the function of forming an electronic wave shielding layer and an adhesive. Hereinafter, the shielding method which in related to the present disclosure will be described.

In the shielding method, a thickness of a slurry to be dispensed varies according to a frequency band of a product, from which an electromagnetic wave is radiated, and metal components of the slurry vary according to the thickness of the slurry.

For example, in the case of a product used in a mobile phone that forms a high-frequency band ranging from 1 GHz to 10 GHz, EMI may be prevented effectively even by dispensing a slurry of a small thickness. In this case, as the thickness of the slurry is small, the amount of the included metal powder is relatively small, and thus, silver (Ag) powder, which is relatively expensive, may be used to manufacture a slurry.

On the other hand, products used in a communication chip such as Bluetooth devices or an engine control unit (ECU) or a transmission control unit (TCU) used in automobiles, create a relatively low frequency band (MHz). Thus, a slurry has to be relatively thick in order to prevent radiation of low-frequency electromagnetic waves to the outside. Due to the relatively thick thickness of the slurry, if expensive silver powder is used, the manufacturing costs may be increased. Thus, in products that form a low-frequency band, a slurry including iron (Fe) powder which is less expensive than silver powder is used in consideration of the thickness of the slurry.

A slurry mixed with metal powder as described above has a relatively high viscosity compared to viscous liquids such as silicon or epoxy and also a low liquidity. In addition, when a slurry is disposed in order to prevent low-frequency band electromagnetic waves, an electromagnetic wave shielding layer having a relatively thick thickness has to be formed, and thus, the amount of a slurry to be dispensed is relatively large.

Accordingly, an apparatus for effectively supplying a slurry having a high viscosity and a lower liquidity is needed.

In addition, when a slurry, which is a mixture of a metal powder such as silver or iron powder and an adhesive, is on a standby state, the metal powder may precipitate and be separated from the adhesive which is liquid. In order to prevent this, an apparatus for effectively dispensing a slurry to an electronic component while maintaining a uniform mixture of a metal powder and an adhesive of the slurry is needed.

### SUMMARY

One or more example embodiments include a slurry dispensing apparatus for electromagnetic interference (EMI) shielding, whereby a slurry having a high viscosity may be effectively dispensed to an electronic component while maintaining a uniform mixture state of the slurry in which a metal powder is not separated from an adhesive by precipitation.

Additional aspects will be set forth in part in the description which follows and, in part, will be apparent from the description, or may be learned by practice of the presented embodiments.

According to one or more example embodiments, a slurry dispensing apparatus for electromagnetic interference (EMI) shielding is included, wherein the slurry dispensing apparatus dispenses a slurry, in which a conductive metal powder and an adhesive are mixed, in order to form an electromagnetic wave shielding layer, and includes: a syringe for storing the slurry; a discharge pipe comprising an inlet connected to the syringe to receive the slurry, a nozzle, through which the slurry received through the inlet is discharged, and a connection flow path configured to connect the inlet and the nozzle; a first circulation pipe branched off from the connection flow path of the discharge pipe and connected to the syringe to transfer the slurry supplied to the connection flow path of the discharge pipe, to the syringe; a first conversion valve mounted in a connection portion between the discharge pipe and the first circulation pipe to selectively open and close a flow of the slurry of the connection flow path of the discharge pipe with respect to the nozzle and the first circulation pipe; and a discharge unit mounted on the connection flow path of the discharge pipe to pressurize the connection flow path such that the slurry flows to the first conversion valve.

### BRIEF DESCRIPTION OF THE DRAWINGS

These and/or other aspects will become apparent and more readily appreciated from the following description of the embodiments, taken in conjunction with the accompanying drawing in which:

FIG. 1 is a structural diagram of a slurry dispensing apparatus for electromagnetic interference (EMI) shielding according to an embodiment of the present disclosure.

### DETAILED DESCRIPTION

A slurry dispensing apparatus for electromagnetic interference (EMI) shielding according to the present invention will now be described more fully with reference to the accompanying drawings.

The slurry dispensing apparatus for EMI shielding according to the present embodiment dispenses a slurry to electronic components in order to form an electromagnetic wave shielding layer. A ‘slurry’ described hereinafter refers to a mixture in which a conductive metal powder and an adhesive are mixed.

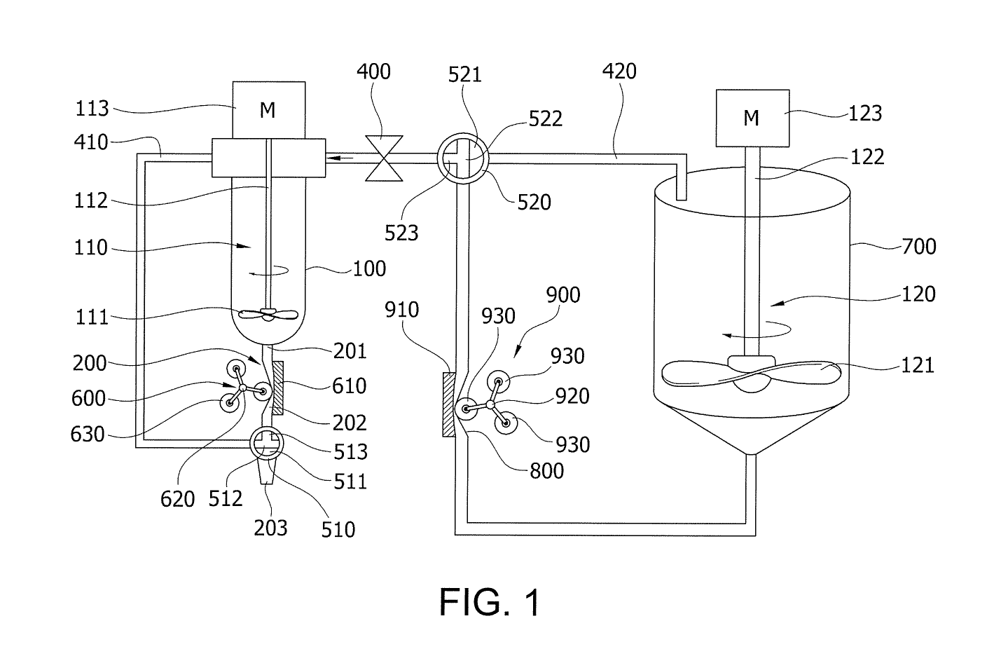

Referring to FIG. 1, the slurry dispensing apparatus for EMI shielding according to the present embodiment includes a syringe 100, a discharge pipe 200, a first circulation pipe 410, a first conversion valve 510, a discharge unit 600, a reservoir 700, a supply pipe 800, a second circulation pipe 420, a second conversion valve 520, and a supply unit 900.

The syringe 100 is filled with a slurry to be dispensed to an electronic component. The syringe 100 is in the form of a container. A first agitating member 110 is rotatably mounted in the syringe 100. The first agitating member 110 agitates the slurry to prevent separation of a metal powder in the slurry from a liquid adhesive by precipitation. The first agitating member 110 according to the present embodiment includes a first agitating axis 112 located in internal space of the syringe 100, a plurality of first agitation blades 111 coupled to the first agitating axis 112, and a first rotation motor 113 rotating the first agitating axis 112.

The discharge pipe 200 is connected to the syringe 100. The discharge pipe 200 includes an inlet 201, a nozzle 203, and a connection flow path 202. The inlet 201 of the discharge pipe 200 is connected to the syringe 100 to receive a slurry. The slurry supplied through the inlet 201 passes by the connection flow path 202 to be transferred to the nozzle 203. The slurry discharged from the nozzle 203 is dispensed to an electronic component. The connection flow path 202 connects the inlet 201 and the nozzle 203. The connection flow path 202 of the discharge pipe 200 is formed of an elastic material. According to the present embodiment, the connection flow path 202 is formed of a soft silicon-based tube or a rubber-based tube. The connection flow path 202 formed of an elastic material as described above is elastically deformed in a diameter direction so that the slurry contained in the connection flow path 202 is moved via a roller 630 which will be described later.

The first circulation pipe 410 is branched off from the connection flow path 202 of the discharge pipe 200 to be connected to the syringe 100. The slurry is circulated again to the syringe 100 along the first circulation pipe 410.

The first conversion valve 510 is mounted in a connection portion between the discharge pipe 200 and the first circulation pipe 410. The first conversion valve 510 selectively opens or closes a flow of the slurry of the connection flow path 202 of the discharge pipe 200 with respect to the nozzle 203 and the first circulation pipe 410. According to the present embodiment, as illustrated in FIG. 1, the first conversion valve 510 is configured, such that a first flow path 512 and a second flow path 513 in a valve body 511 cross each other in a T-shape and are fluidly connected to each other.

The discharge unit 600 is mounted on the connection flow path 202 of the discharge pipe 200. The discharge unit 600 pressurizes the connection flow path 202 so that the slurry flows to the first conversion valve 510. The discharge unit 600 includes a flow path support 610, a discharge rotational axis 620, and a plurality of rollers 630.

As illustrated in FIG. 1, the flow path support 610 is mounted at a side of the connection flow path 202 to support the connection flow path 202. The discharge rotational axis 620 is rotatably mounted at a location separated from the flow path support 610. Three rollers 630 are mounted on the discharge rotational axis 620. The three rollers 630 are each arranged at an identical radius from the discharge rotational axis 620 along a circumferential direction. When the discharge rotational axis 620 rotates, the three rollers 630 roll while sequentially pressurizing the connection flow path 202 with respect to the flow path support 610.

The reservoir 700 stores a slurry to be used to replenish the syringe 100. A second agitating member 120 is rotatably mounted in the reservoir 700. The second agitating member 120 maintains a uniform mixture of the slurry in the reservoir 700 and prevents deposition of the slurry on an internal wall of the reservoir 700. In addition, the second agitating member 120 prevents separation of the metal powder included in the slurry from the liquid adhesive by precipitation.

The second agitating member 120 includes a second agitating axis 122 located in an internal space of the reservoir 700, a plurality of second agitation blades 121 coupled to the second agitating axis 122, and a second rotation motor 123 rotating the second agitating axis 122.

A supply pipe 800 is connected to the reservoir 700. The supply pipe 800 connects the reservoir 700 and the syringe 100 to supply a slurry in the reservoir 700 to the syringe 100. The supply pipe 800 is also formed of an elastic material like the discharge pipe 200. According to the present embodiment, the supply pipe 800 is formed of a soft silicon-based or rubber-based tube. The supply pipe 800 formed of an elastic material is elastically deformed in a diameter direction such that the slurry may be moved via a roller 930 which will be described later.

The second circulation pipe 420 is branched off from the supply pipe 800 and is connected to the reservoir 700 again. The slurry moving along the supply pipe 800 is circulated to the reservoir 700 via the second circulation pipe 420.

The second conversion valve 520 is mounted in a connection portion between the supply pipe 800 and the second circulation pipe 420. The second conversion valve 520 selectively opens or closes a flow of the slurry in the supply pipe 800 with respect to the syringe 100 and the second circulation pipe 420. Like the first conversion valve 510, the second conversion valve 520 is rotatably mounted to the connection portion between the supply pipe 800 and the second circulation pipe 420. According to the present embodiment, like in the first conversion valve 510, a first flow path 522 and a second flow path 523 cross each other in a T-shape and are fluidly connected to each other inside a vale body 521 in the second conversion valve 520.

The supply unit 900 is mounted to the supply pipe 800. The supply unit 900 pressurizes the supply pipe 800 such that the slurry flows to the second conversion valve 520. Like the discharge unit 600, the supply unit 900 also includes a supply support 910, a supply rotational axis 920, and a plurality of rollers 930.

As illustrated in FIG. 1, the supply support 910 is mounted on a side of the supply pipe 800 to support the supply pipe 800. The supply rotational axis 920 is rotatably mounted to the supply support 910 at a distance from the supply support 910. Three rollers 930 are arranged at an identical radius along a circumferential direction and at an identical angle distance from the supply rotational axis 920. The three rollers 930 roll while sequentially pressurizing the first side of the supply pipe 800 with respect to the supply support 910.

Meanwhile, the reservoir 700 has a concave bottom portion. The supply pipe 800 is connected to a lowest point in the concavely formed reservoir 700. Metal powder precipitated from the slurry may precipitate in the concavely formed area in the reservoir 700. As the supply pipe 800 is connected to the lowest point in the reservoir 700, a portion of the slurry that is located at the lowest point in the reservoir 700 may be discharged first and supplied into the syringe 100.

A supply flowmeter 400 is mounted between the syringe 100 and the second conversion valve 520. The supply flowmeter 400 measures a supply amount of the slurry supplied to the syringe 100.

Hereinafter, an operation of the slurry dispensing apparatus for EMI shielding of the embodiment configured as described above will be described.

First, an operation of the slurry dispensing apparatus will be described with respect to the reservoir 700, from which a slurry is transferred to replenish the syringe 100.

As the second agitating member 120 mounted in the reservoir 700 is operated, the slurry in the reservoir 700 is agitated. The plurality of second agitation blades 121 rotate via operation of the second rotation motor 123 coupled to the second agitating axis 122, thereby agitating the slurry. According to the operation of the second agitating member 120 as described above, precipitation of metal powder of the slurry is prevented, and a mixture ratio between the metal powder and the adhesive is maintained uniform.

An operator may operate the second conversion valve 520 to circulate the slurry or supply the slurry to the syringe 100. When the supply pipe 800 and the second circulation pipe 420 are connected via the second conversion valve 520, the slurry in the lower portion of the reservoir 700 flows along the supply pipe 800 to return to the reservoir 700 through the second circulation pipe 420. When replenishing the syringe 100 with the slurry, the valve body 521 of the second conversion valve 520 is rotated so as to connect the supply pipe 800 and the syringe 100 via the first flow path 522 and the second flow path 523 of the second conversion valve 520.

The supply unit 900 pumps the slurry in the supply pipe 800 such that the slurry in the supply pipe 800 flows along the supply pipe 800. When the supply rotational axis 920 of the supply unit 900 is rotated, the three rollers 930 sequentially pressurize the supply pipe 800 to elastically deform the supply pipe 800, thereby pumping the slurry in the supply pipe 800 along the supply pipe 800. The supply support 910 supports the supply pipe 800 with respect to the rollers 930 so as to facilitate elastic deformation of the supply pipe 800 by the rollers 930. The slurry in which metal powder is mixed is frequently highly viscous, and by using the supply unit 900 having the above-described structure, the highly viscous slurry may also be effectively supplied.

When the slurry in the reservoir 700 is agitated and circulated to the reservoir 700 as described above, following effects may be obtained.

Separation of metal powder of the slurry from the adhesive by precipitation may be prevented and deposition of the slurry on an inner wall of the reservoir 700 may be prevented. In addition, by continuously circulating the slurry that is used to replenish the syringe 100, the syringe 100 may be replenished with the slurry including uniform components.

As described above, the supply pipe 800 may be connected to the lowest point in the reservoir 700. According to the structure, the slurry that is located at the lowest portion in the reservoir 700 is first discharged to replenish the syringe 100 or is circulated to the reservoir 700. If the slurry is accumulated in the reservoir 700, the slurry may be adhered to the inner wall of the reservoir 700 as time passes, and the inconvenience of having to clean the reservoir 700 may be aroused. However, when the slurry is replenished into the syringe 100 or circulated again to the reservoir 700 by discharging first the slurry located in the lower portion in the reservoir 700 through the supply pipe 800 connected to the lower portion of the reservoir 700 as described above, the above problem may be prevented.

Meanwhile, an operator may measure an amount of the slurry supplied to the syringe 100 by using the supply flowmeter 400. If the amount of the slurry supplied to the syringe 100 is determined to be excessive, a rotational speed of the supply rotational axis 920 may be reduced to adjust the amount of the supplied slurry. In addition, by measuring the amount of the slurry supplied to the syringe 100, by using the supply flowmeter 400, a degree of agitation of the slurry in the syringe 100 may be predicted, and a rotational speed of the first rotational motor 113 in the syringe 100 may be adjusted such that components of the slurry are maintained uniform.

When the slurry in the reservoir 700 is used to replenish the syringe 100 as described above, the slurry stored in the syringe 100 may be used and dispensed to electronic components.

Hereinafter, an operational relationship with respect to the syringe 100 will be described.

First, an operation of circulating the slurry stored in the syringe 100 will be described.

The first agitating member 110 prevents deposition of the slurry in the syringe 100 on an inner wall of the syringe 100, and prevents separation of the metal powder in the slurry from the adhesive by precipitation so as to maintain uniformity of the components of the slurry. The plurality of agitation blades 111 agitate the slurry by rotating via an operation of the first rotation motor 113 coupled to the first agitating axis 112.

When an operator rotates a valve body 511 of the first conversion valve 510 so as to connect the connection flow path 202 of the discharge pipe 200 and the first circulation pipe 410 via the first flow path 512 and the second flow path 513, the slurry flows from the inlet 201 of the discharge pipe 200 connected to the syringe 100 to pass through the connection flow path 202 and then flow to the first circulation pipe 410.

The discharge unit 600 pumps the slurry in the connection flow path 202 such that the slurry in the connection flow path 202 of the discharge pipe 200 flows along the connection flow path 202. When the discharge rotational axis 620 of the discharge unit 600 is rotated, the three rollers 630 sequentially pressurize the connection flow path 202 to deform the connection flow path 202, thereby moving the slurry in the connection flow path 202 along the connection flow path 202. Here, the flow path support 610 supports the connection flow path 202 with respect to the rollers 530 to thereby facilitate elastic deformation of the connection flow path 202 by the rollers 630. The slurry in which metal powder is mixed is frequently highly viscous, and by using the discharge unit 600 having the above-described structure, the slurry having a high viscosity may be effectively pumped.

The slurry has a high viscosity as a conductive metal powder and an adhesive such as an epoxy are mixed in the slurry. The highly viscous slurry has a high possibility of deposition, and thus, it is difficult to move the slurry through flow paths by using a typical pump. By considering this, the slurry dispensing apparatus for EMI shielding according to the present embodiment includes the discharge unit 600 that operates in a peristaltic pump manner and the connection flow path 202 that is formed of an elastic material, and accordingly, the highly viscous slurry may be effectively pumped.

The highly viscous slurry flows smoothly and circulates while maintaining a uniform state by using the discharge unit 600 that operates in a peristaltic pump manner and through the connection flow path 202 formed of an elastic material. In addition, as the slurry is continuously circulated, pollution that may be caused by accumulation of the slurry in the syringe 100 may be prevented.

Hereinafter, an operation of dispensing a slurry to an electronic component will be described.

When an operator operates the first conversion valve 510 to connect the connection flow path 202 and the nozzle 203 of the discharge pipe 200 via the first flow path 512 of the first conversion valve 510, the slurry of the syringe 100 is discharged through the nozzle 203 via an operation of the discharge unit 600. The slurry discharged through the nozzle 203 is dispensed to an electronic component disposed below the nozzle 203. The first agitating member 110 in the syringe 100 operates continuously while the slurry is dispensed to electronic components, thereby maintaining components of the slurry uniform.

The syringe 100, the discharge pipe 200, the first conversion valve 510, and the discharge unit 600 may be mounted on a transporting member to be transported forward and backward and to the left and to the right. In this case, a slurry dispensing operation may be sequentially performed on a plurality of electronic component disposed below the above-described elements.

As described above, as the slurry is continuously circulated with respect to the syringe 100 before being dispensed to an electronic component, a density of the metal powder is maintained uniform. In addition, the highly viscous slurry may be stably supplied to the nozzle 203 via the discharge unit 600, and thus, an exact amount wished by the operator may be dispensed to an electronic component.

While the present invention has been described with reference to preferred embodiments above, the scope of the present invention is not limited to the embodiments described above and illustrated in the drawings.

For example, while the embodiment has been described above, in which the syringe 100, the discharge pipe 200, the first circulation pipe 410, and the first conversion valve 510 that are used to dispense a slurry, and the discharge unit 600, the reservoir 700, through which the slurry is supplied into the syringe 100, and other peripheral components are included, the slurry dispensing apparatus according to the present invention may also include only a syringe and a discharge unit to dispense a slurry, and may not include a reservoir and peripheral components. In this case, a reservoir having a different structure than the above-described structure may be connected to the slurry dispensing apparatus, and the slurry dispensing apparatus having a structure not including a reservoir and peripheral components thereof may be manufactured to be produced, sold or used.

In addition, as illustrated in FIG. 1 above, while the embodiment in which the slurry in the reservoir 700 is also circulated to replenish the syringe 100 with the slurry has been described above, an embodiment in which a reservoir storing a slurry is connected to a syringe to replenish the syringe with the slurry, without circulating the slurry in the reservoir, may also be implemented.

In addition, the first conversion valve 510 and the second conversion valve 520 may also have other various configurations such as a structure in which flow paths may be selectively opened or closed.

In addition, while it is described that the operator rotates the valve bodies 511 and 521 of the first conversion valve 510 and the second conversion valve 520, the embodiments are not limited thereto. A controller that is additionally provided may be used to operate a first conversion valve and a second conversion valve via an electrical signal.

In this case, the controller receives an amount of a slurry measured using a supply flowmeter. The controller controls a rotational speed of a supply rotational axis such that a desired amount of a slurry by the operator is supplied to the syringe. In addition, an amount of a slurry supplied to the syringe may be transmitted to the controller to predict a present amount of the slurry in the syringe, and an operation of a first rotational motor may be controlled to adjust a degree of agitation in the syringe based on the predicted amount of the slurry. In addition, if the amount of the slurry supplied to the syringe is determined to be excessive, a rotational speed of the discharge rotational axis may be controlled.

A viscosity measuring sensor for measuring a viscosity of the slurry may be further mounted in the supply flowmeter. A viscosity of the slurry sensed using the viscosity measuring sensor is transmitted to the controller, and the controller may adjust rotational speeds of a first rotational motor and a second rotational motor such that a viscosity of the slurry wished by the operator is maintained.

According to the slurry dispensing apparatus for EMI shielding, a slurry may be dispensed while preventing separation of a metal powder included in the slurry from an adhesive by precipitation and maintaining a uniform mixture ratio in the slurry.

While one or more example embodiments have been described with reference to the figures, it will be understood by those of ordinary skill in the art that various changes in form and details may be made therein without departing from the spirit and scope of the inventive concept as defined by the following claims.

What is claimed is:

1. A slurry dispensing apparatus for electromagnetic interference (EMI) shielding, wherein the slurry dispensing apparatus dispenses a slurry, in which a conductive metal powder and an adhesive are mixed, in order to form an electromagnetic wave shielding layer, the slurry dispensing apparatus comprising:
a syringe for storing the slurry;
a discharge pipe comprising an inlet connected to the syringe to receive the slurry, a nozzle, through which the slurry received through the inlet is discharged, and a connection flow path configured to connect the inlet and the nozzle;
a first circulation pipe branched off from the connection flow path of the discharge pipe and connected to the syringe to transfer the slurry supplied to the connection flow path of the discharge pipe, to the syringe;
a first conversion valve mounted in a connection portion between the discharge pipe and the first circulation pipe to selectively open and close a flow of the slurry of the connection flow path of the discharge pipe with respect to the nozzle and the first circulation pipe; and
a discharge unit mounted on the connection flow path of the discharge pipe to pressurize the connection flow path such that the slurry flows to the first conversion valve.

2. The slurry dispensing apparatus for EMI shielding of claim 1, further comprising a first agitating member that is rotatably mounted in the syringe to agitate the slurry stored in the syringe.

3. The slurry dispensing apparatus for EMI shielding of claim 1, wherein the connection flow path of the discharge pipe is formed of an elastic material, and
the discharge unit comprises a flow path support supporting the connection flow path, a discharge rotational axis that is rotatably mounted at a location separated from the flow path support, and a plurality of rollers that are each arranged at an identical radius from the discharge rotational axis along a circumferential direction, wherein the plurality of rollers roll while sequentially pressurizing the connection flow path with respect to the flow path support when the discharge rotational axis rotates.

4. The slurry dispensing apparatus for EMI shielding of claim 1, further comprising:
a reservoir configured to store the slurry to be used to replenish the syringe;
a supply pipe configured to connect the reservoir and the syringe so as to supply the slurry stored in the reservoir to the syringe;
a second circulation pipe branched off from the supply pipe to transfer the slurry of the supply pipe to the reservoir;
a second conversion valve mounted in a connection portion between the supply pipe and the second circulation pipe and configured to selectively open and close a flow of the slurry of the supply pipe with respect to the syringe and the second circulation pipe; and
a supply unit mounted to the supply pipe and configured to pressurize the supply pipe such that the slurry flows to the second conversion valve.

5. The slurry dispensing apparatus for EMI shielding of claim 4, further comprising a second agitating member that is rotatably mounted in the reservoir to agitate the slurry stored in the reservoir.

6. The slurry dispensing apparatus for EMI shielding of claim 5, wherein the supply pipe is formed of an elastic material, and
wherein the supply unit comprises a supply support for supporting the supply pipe, a supply rotational axis that is rotatably mounted at a location separated from the supply support, and a plurality of rollers that are each arranged at an identical radius from the supply rotational axis along a circumferential direction, wherein the plurality of rollers roll while sequentially pressurizing the supply pipe with respect to the supply pipe when the supply rotational axis rotates.

7. The slurry dispensing apparatus for EMI shielding of claim 4, wherein the reservoir has a concave lower portion,
wherein the supply pipe is connected to a lowest point in the reservoir.

8. The slurry dispensing apparatus for EMI shielding of claim 4, further comprising a supply flowmeter mounted to the supply pipe to measure a supply amount of the slurry supplied through the supply pipe.
